(19) United States
(12) Patent Application Publication
(10) Pub. No.: US 2025/0150057 A1
(43) Pub. Date: May 8, 2025

(54) ACOUSTIC WAVE DEVICE

(71) Applicant: Murata Manufacturing Co., Ltd., Nagaokakyo-shi (JP)

(72) Inventors: Hiromu OKUNAGA, Nagaokakyo-shi (JP); Hideki IWAMOTO, Nagaokakyo-shi (JP)

(21) Appl. No.: 19/013,252

(22) Filed: Jan. 8, 2025

Related U.S. Application Data
(63) Continuation of application No. PCT/JP2023/020538, filed on Jun. 1, 2023.

(30) Foreign Application Priority Data
Jul. 15, 2022 (JP) 2022-113606

(51) Int. Cl. H03H 9/145; H03H 9/02; H03H 9/25

(52) U.S. Cl. CPC H03H 9/14541; H03H 9/02559; H03H 9/02637; H03H 9/25

(57) ABSTRACT

An acoustic wave device includes a support board, an intermediate layer on the support board, a piezoelectric layer on the intermediate layer, and including first and second main surfaces, a first IDT electrode at the first main surface, and embedded in the intermediate layer, and a second IDT electrode at the second main surface. The first IDT electrode includes electrode fingers each including first and second surfaces opposed to each other in a thickness direction of the electrode fingers, and a side surface connected to the first and second surfaces. The side surface of each of the electrode fingers includes first and second portions, and in at least one of the electrode fingers, the first and second portions have different angles of inclination with respect to the thickness direction.

### CROSS REFERENCE TO RELATED APPLICATIONS

This application claims the benefit of priority to Japanese Patent Application No. 2022-113606 filed on Jul. 15, 2022 and is a Continuation application of PCT Application No. PCT/JP2023/020538 filed on Jun. 1, 2023. The entire contents of each application are hereby incorporated herein by reference.

### BACKGROUND OF THE INVENTION

### 1. Field of the Invention

The present invention relates to acoustic wave devices.

### 2. Description of the Related Art

Acoustic wave devices have been widely used for, for example, filters of mobile phones. Japanese Unexamined Patent Application Publication No. 2021-044835 discloses a plate-type waveguide device as an example of an acoustic wave device. The example of the acoustic wave device described in Japanese Unexamined Patent Application Publication No. 2021-044835 includes interdigital transducers (IDT) on both surfaces of a piezoelectric layer. Both IDTs are covered with slow-wave propagation layers.

While being manufactured or used, an acoustic wave device may receive an external force or thermal stress resulting from a temperature change. When a force as described above is exerted on the acoustic wave device described in Japanese Unexamined Patent Application Publication No. 2021-044835, the IDTs and the slow-wave propagation layer are more likely to be separated from each other. In such a case, the acoustic wave device may fail to obtain intended electric characteristics.

### SUMMARY OF THE INVENTION

Example embodiments of the present invention provide acoustic wave devices each reducing or preventing separation between an IDT electrode and a layer covering the IDT electrode.

An example embodiment of the present invention provides an acoustic wave device that includes a support board, an intermediate layer on the support board, a piezoelectric layer on the intermediate layer, and including a first main surface located closer to the intermediate layer and a second main surface opposed to the first main surface, a first IDT electrode at the first main surface of the piezoelectric layer, and embedded in the intermediate layer, and a second IDT electrode at the second main surface of the piezoelectric layer, wherein the first IDT electrode includes a plurality of electrode fingers each including a first surface and a second surface opposed to each other in a thickness direction of the electrode finger, and a side surface connected to the first surface and the second surface, and the side surface of each of the plurality of electrode fingers of the first IDT electrode includes a first portion and a second portion, and in at least one of the plurality of electrode fingers, the first portion and the second portion have different angles of inclination with respect to the thickness direction of the electrode finger.

Acoustic wave devices according to example embodiments of the present invention each reduce or prevent separation between an IDT electrode and a layer covering the IDT electrode.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a cross-sectional front view of an acoustic wave device according to a first example embodiment of the present invention.

FIG. 2 is a bottom view of an electrode structure on a first main surface of a piezoelectric layer according to the first example embodiment of the present invention.

FIG. 3 is a cross-sectional front view of the acoustic wave device according to the first example embodiment of the present invention, at a portion near two pairs of electrode fingers in each of a first IDT electrode and a second IDT electrode.

FIG. 4 is a cross-sectional front view of an acoustic wave device according to a second example embodiment of the present invention, at a portion near two pairs of electrode fingers in each of a first IDT electrode and a second IDT electrode.

FIG. 5 is a cross-sectional front view of an acoustic wave device according to a third example embodiment of the present invention, at a portion near two pairs of electrode fingers in each of a first IDT electrode and a second IDT electrode.

FIG. 6 is a cross-sectional front view of an acoustic wave device according to a fourth example embodiment of the present invention, at a portion near two pairs of electrode fingers in each of a first IDT electrode and a second IDT electrode.

FIG. 7 is a cross-sectional front view of an acoustic wave device according to a modified example of the fourth example embodiment of the present invention, at a portion near two pairs of electrode fingers in each of a first IDT electrode and a second IDT electrode.

FIG. 8 is a schematic plan view of an acoustic wave device according to a fifth example embodiment of the present invention.

FIG. 9 is a graph of impedance frequency characteristics of the first example embodiment and the fifth example embodiment of the present invention.

FIG. 10 is a schematic plan view of an acoustic wave device according to a sixth example embodiment of the present invention.

FIG. 11 is a cross-sectional front view of an acoustic wave device according to a seventh example embodiment of the present invention, at a portion near two pairs of electrode fingers in each of a first IDT electrode and a second IDT electrode.

FIG. 12 is a cross-sectional front view of an acoustic wave device according to a modified example of the seventh example embodiment of the present invention.

### DETAILED DESCRIPTION OF THE EXAMPLE EMBODIMENTS

Hereinbelow, with reference to the drawings, example embodiments of the present invention are described to clarify the present invention.

Example embodiments described herein are mere examples, and components between difference example embodiments may be partially replaced or combined with each other.

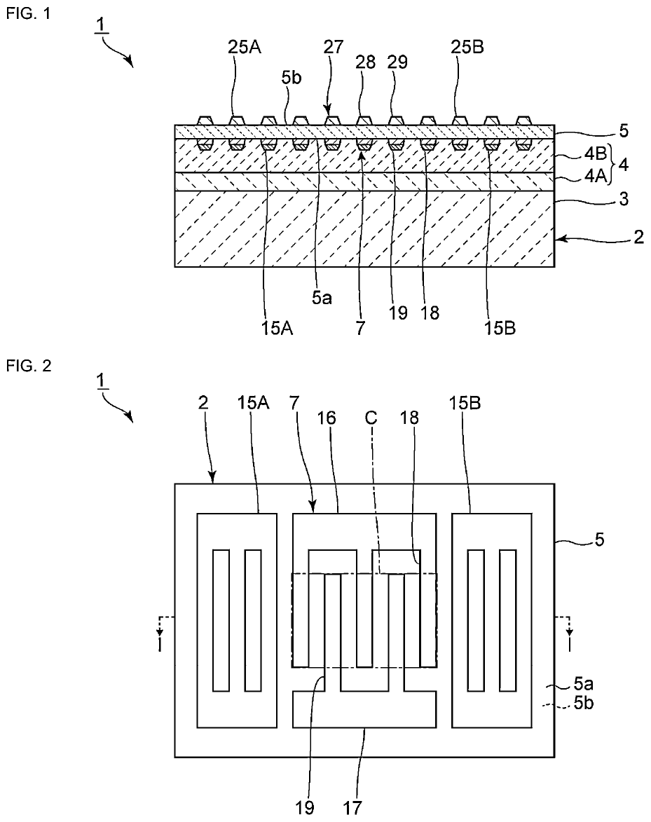

FIG. 1 is a cross-sectional front view of an acoustic wave device according to a first example embodiment of the present invention.

An acoustic wave device 1 includes a piezoelectric substrate 2. The piezoelectric substrate 2 includes a support board 3, an intermediate layer 4, and a piezoelectric layer 5. In the present example embodiment, the intermediate layer 4 is a multilayer body. More specifically, the intermediate layer 4 includes a first layer 4A and a second layer 4B. The first layer 4A of the intermediate layer 4 is disposed on the support board 3. The second layer 4B is disposed on the first layer 4A. The piezoelectric layer 5 is disposed on the second layer 4B. The intermediate layer 4 may be, for example, a single dielectric layer.

The piezoelectric layer 5 includes a first main surface 5a and a second main surface 5b. The first main surface 5a and the second main surface 5b are opposed to each other. Of the first main surface 5a and the second main surface 5b, the first main surface 5a is located closer to the intermediate layer 4. A first IDT electrode 7 is disposed at the first main surface 5a of the piezoelectric layer 5. The first IDT electrode 7 is embedded in the intermediate layer 4. In contrast, a second IDT electrode 27 is disposed at the second main surface 5b of the piezoelectric layer 5.

FIG. 2 is a bottom view of an electrode structure on the first main surface of the piezoelectric layer according to the first example embodiment. FIG. 1 is a cross-sectional view of the acoustic wave device according to the first example embodiment taken along line I-I in FIG. 2.

The first IDT electrode 7 includes a pair of busbars, multiple first electrode fingers 18, and multiple second electrode fingers 19. More specifically, the pair of busbars include a first busbar 16 and a second busbar 17. The first busbar 16 and the second busbar 17 face each other. One end of each of the multiple first electrode fingers 18 is connected to the first busbar 16. One end of each of the multiple second electrode fingers 19 is connected to the second busbar 17. The multiple first electrode fingers 18 and the multiple second electrode fingers 19 are interdigitated with one another. The first electrode fingers 18 and the second electrode fingers 19 are connected to different potentials.

Similarly, the second IDT electrode 27 illustrated in FIG. 1 also includes a pair of busbars, multiple third electrode fingers 28, and multiple fourth electrode fingers 29. More specifically, the pair of busbars in the second IDT electrode 27 include a third busbar and a fourth busbar. The third busbar and the fourth busbar face each other. One end of each of the multiple third electrode fingers 28 is connected to the third busbar. One end of each of the multiple fourth electrode fingers 29 is connected to the fourth busbar. The multiple third electrode fingers 28 and the multiple fourth electrode fingers 29 are interdigitated with one another. The third electrode fingers 28 and the fourth electrode fingers 29 are connected to different potentials.

Hereinbelow, the first electrode fingers 18, the second electrode fingers 19, the third electrode fingers 28, and the fourth electrode fingers 29 may be simply referred to as electrode fingers. In each of the first IDT electrode 7 and the second IDT electrode 27, the direction in which the multiple electrode fingers extend is referred to as an electrode-finger extension direction. In the present example embodiment, the electrode-finger extension direction of the first IDT electrode 7 and the electrode-finger extension direction of the second IDT electrode 27 are parallel or substantially parallel to each other.

When an alternating current voltage is applied to the first IDT electrode 7 and the second IDT electrode 27, an acoustic wave is excited. In the present example embodiment, an acoustic-wave propagation direction is orthogonal or substantially orthogonal to the electrode-finger extension direction. A pair of reflectors 15A and 15B are disposed at the first main surface 5a of the piezoelectric layer 5. The reflector 15A and the reflector 15B face each other in the direction orthogonal or substantially orthogonal to the electrode-finger extension direction with the first IDT electrode 7 interposed therebetween. Similarly, a pair of reflectors 25A and 25B are disposed at the second main surface 5b. The reflector 25A and the reflector 25B face each other in the direction orthogonal or substantially orthogonal to the electrode-finger extension direction with the second IDT electrode 27 interposed therebetween.

In the present example embodiment, the first IDT electrode 7, the reflector 15A, and the reflector 15B are formed by, for example, laminating a Pt layer and an Al layer in this order from the piezoelectric layer 5. In contrast, the second IDT electrode 27, the reflector 25A, and the reflector 25B include, for example, an Al layer. Nevertheless, the materials and the number of layers of the first IDT electrode 7, the second IDT electrode 27, and each reflector are not limited to the above examples. The first IDT electrode 7, the reflector 15A, and the reflector 15B may include, for example, a laminate metal film including three or more layers, or a single metal film. Similarly, the second IDT electrode 27, the reflector 25A, and the reflector 25B may include a laminate metal film.

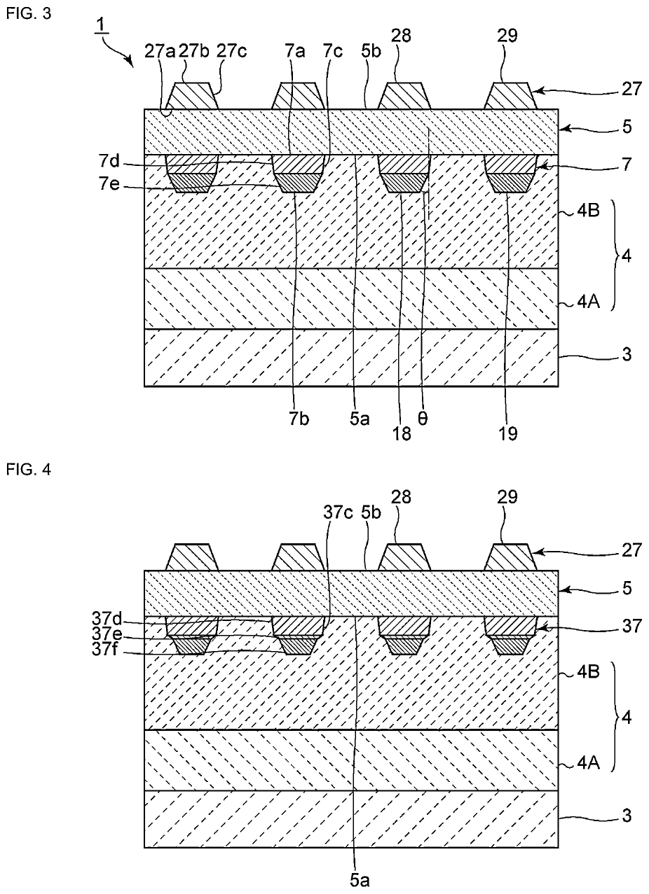

FIG. 3 is a cross-sectional front view of the acoustic wave device according to the first example embodiment, at a portion near two pairs of electrode fingers in each of a first IDT electrode and a second IDT electrode.

Each electrode finger of the first IDT electrode 7 includes a first surface 7a, a second surface 7b, and a side surface 7c. The first surface 7a and the second surface 7b are opposed to each other in a thickness direction of each electrode finger. Of the first surface 7a and the second surface 7b, the first surface 7a is located closer to the piezoelectric layer 5. The side surface 7c is a surface connecting the first surface 7a and the second surface 7b to each other. The side surface 7c of each electrode finger includes a first portion 7d and a second portion 7e. More specifically, the first portion 7d and the second portion 7e are arranged in the thickness direction of each electrode finger. Of the first portion 7d and the second portion 7e, the first portion 7d is located closer to the piezoelectric layer 5. The end portion of the first portion 7d closer to the support board 3 is connected to the end portion of the second portion 7e closer to the piezoelectric layer 5. In the present example embodiment, the first portion 7d of the side surface 7c is, for example, a side surface of a Pt layer, the second portion 7e of the side surface 7c is, for example, a side surface of an Al layer.

An angle θ of the side surface 7c of each electrode finger inclined with respect to the thickness direction of each electrode finger is defined as an angle of inclination. When the side surface 7c of electrode finger is inclined to reduce the width of the electrode finger further as it extends farther from the piezoelectric layer 5, an angle of inclination has a positive value. In contrast, when the side surface 7c is inclined to increase the width of the electrode finger further as it extends farther from the piezoelectric layer 5, an angle of inclination has a negative value. The width of the electrode finger is a dimension of the electrode finger in the direction orthogonal or substantially orthogonal to the electrode-finger extension direction. In the first IDT electrode 7 of the acoustic wave device 1, the side surface 7c of each electrode finger is inclined to reduce the width of the electrode finger further as it extends farther from the piezoelectric layer 5.

In the present example embodiment, in the first IDT electrode 7 embedded in the intermediate layer 4, the side surface 7c of each electrode finger has the first portion 7d and the second portion 7e, and the angle of inclination of the first portion 7d and the angle of inclination of the second portion 7e are different from each other. The angle of inclination of the first portion 7d and the angle of inclination of the second portion 7e may be different from each other for at least one electrode finger. Thus, the contact area between each electrode finger and the intermediate layer 4 can be increased, and the adhesion properties between each electrode finger and the intermediate layer 4 can be improved. Thus, the joining force between the first IDT electrode 7 and the intermediate layer 4 can be improved. This structure reduces or prevents separation between the first IDT electrode 7 and the intermediate layer 4 covering the first IDT electrode 7.

The first IDT electrode 7 can be formed by, for example, a lift-off method including vacuum deposition or sputtering. The angle of inclination of the first portion 7d and the angle of inclination of the second portion 7e can be varied by varying the deposition rate at which the portion of each electrode finger including the first portion 7d is formed and the deposition rate at which the portion of each electrode finger including the second portion 7e is formed. Nevertheless, the method for forming the first IDT electrode 7 is not limited to the above example. The angle of inclination of the first portion 7d and the angle of inclination of the second portion 7e may be varied by, for example, etching.

The structure of the present example embodiment is further described in detail below.

As illustrated in FIG. 2, in the first IDT electrode 7, when viewed in the direction orthogonal or substantially orthogonal to the electrode-finger extension direction, an area where adjacent electrode fingers overlap is an intersecting area C. Similarly, the second IDT electrode 27 also includes an intersecting area. The intersecting area C in the first IDT electrode 7 and the intersecting area in the second IDT electrode 27 overlap in a plan view. Herein, the plan view refers to a view from a direction corresponding to above in FIG. 1. In FIG. 1, for example, of the piezoelectric layer 5 and the support board 3, the piezoelectric layer 5 is located above the support board 3.

The centers of the multiple electrode fingers in the intersecting area C of the first IDT electrode 7 and the centers of the multiple electrode fingers in the intersecting area of the second IDT electrode 27 overlap in a plan view. Instead, at least portions of the multiple electrode fingers of the first IDT electrode 7 and at least portions of the multiple electrode fingers of the second IDT electrode 27 may overlap in a plan view. Both intersecting areas may be disposed in any state to overlap in a plan view within a tolerance range that does not largely affect the electric characteristics of the acoustic wave device. Thus, variations resulting from the manufacturing tolerance are included within a range where both intersecting areas overlap in a plan view.

The first IDT electrode 7 and the second IDT electrode 27 have the same or substantially the same electrode finger pitch. The electrode finger pitch is a distance between the centers of adjacent electrode fingers. Herein, the same or substantially the same electrode finger pitch includes a range where the electrode finger pitches vary within a tolerance range that does not largely affect the electric characteristics of the acoustic wave device.

In the present example embodiment, the third electrode fingers 28 of the second IDT electrode 27 illustrated in FIG. 1 are connected to the same potential as either the first electrode fingers 18 of the first IDT electrode 7 or the second electrode fingers 19 of the first IDT electrode 7. The fourth electrode fingers 29 are connected to the same potential as the other electrode fingers of the first electrode fingers 18 and the second electrode fingers 19.

In the present example embodiment, the potentials of the electrode fingers overlapping in a plan view coincide. Nevertheless, the relationship in potential between the electrode fingers of the first IDT electrode 7 and the electrode fingers of the second IDT electrode 27 is not limited to the above example. For example, the potentials of at least one pair of electrode fingers of the multiple pairs overlapping in a plan view may coincide.

The potentials of the reflector 15A, the reflector 15B, the reflector 25A, and the reflector 25B may be the same as the potential of the first electrode fingers 18 of the first IDT electrode 7, or the potential of the second electrode fingers 19 of the first IDT electrode 7. Alternatively, each reflector may include a floating electrode. A floating electrode refers to an electrode not connected to a signal potential and a ground potential.

In the acoustic wave device 1, for example, silicon is used as a material of the support board 3. Nevertheless, the material of the support board 3 is not limited to the above example. For example, a piezoelectric substance such as aluminum nitride, lithium tantalate, lithium niobate, or a crystal, ceramics such as alumina, sapphire, magnesia, silicon nitride, silicon carbide, zirconia, cordierite, mullite, steatite, or forsterite, a dielectric substance such as diamond or glass, a semiconductor such as silicon or gallium nitride, a resin, or a material including any of the above materials as a main component may be used. Herein, the main component refers to a component that occupies higher than 50 wt % in the entire material. The material of the main component may be in a single crystalline state, a polycrystalline state, or an amorphous state, or in a state of mixture of these states.

Silicon nitride, for example, is used as a material of the first layer 4A of the intermediate layer 4. Nevertheless, the material of the first layer 4A is not limited to the above example. For example, a piezoelectric substance such as aluminum nitride, lithium tantalate, lithium niobate, or a crystal, ceramics such as alumina, sapphire, magnesia, silicon nitride, silicon carbide, zirconia, cordierite, mullite, steatite, forsterite, spinel, or sialon, a dielectric substance such as aluminum oxide, oxynitride silicon, diamond-like carbon (DLC), or diamond, a semiconductor such as silicon, or a material including any of the above materials as a main component may be used. Spinel described above includes, for example, an aluminum compound including oxygen and one or more elements selected from, for example, Mg, Fe, Zn, pr Mn. Examples of spinel include MgAl₂O₄, FeAl₂O₄, ZnAl₂O₄, or MnAl₂O₄.

Silicon oxide, for example, is used as a material of the second layer 4B of the intermediate layer 4. Nevertheless, the material of the second layer 4B is not limited to the above example. For example, glass, silicon oxide, oxynitride silicon, lithium oxide, tantalum oxide, a dielectric substance such as a compound obtained by adding fluorine, carbon or boron to silicon oxide, or a material including any of the above materials as a main component may be used.

In the above description, an example of the material of the first layer 4A of the intermediate layer 4 is different from an example of the material of the second layer 4B of the intermediate layer 4. Nevertheless, the material described as an example of the material of the first layer 4A may be used as a material of the second layer 4B. The material described as an example of the second layer 4B may be used as a material of the first layer 4A. The number of layers included in the intermediate layer 4 is not limited to a particular one, and may be one layer or three or more layers. When the intermediate layer 4 includes multiple layers, the multiple layers may be made of different materials.

Lithium niobate, for example, is used as a material of the piezoelectric layer 5. Nevertheless, the material of the piezoelectric layer 5 is not limited to the above example. For example, lithium tantalate, zinc oxide, aluminum nitride, a crystal, or lead zirconate titanate (PZT) may be used.

Herein, the state where the first IDT electrode 7 is embedded in the intermediate layer 4 refers to a state where the side surfaces 7c of the multiple electrode fingers of the first IDT electrode 7 are in contact with the intermediate layer 4. For example, even when the second surfaces 7b of the multiple electrode fingers are in contact with a member other than the intermediate layer 4, the first IDT electrode 7 is regarded as being embedded in the intermediate layer 4.

In the present example embodiment, a portion of the intermediate layer 4 in which the first IDT electrode 7 is embedded corresponds to the second layer 4B. The material of the second layer 4B and the material of the piezoelectric layer 5 differ from each other. Instead, the material of the portion of the intermediate layer 4 in which the first IDT electrode 7 is embedded and the material of the piezoelectric layer 5 may be the same.

As illustrated in FIG. 1, the first IDT electrode 7 is directly disposed at the first main surface 5a of the piezoelectric layer 5. Instead, the first IDT electrode 7 may be indirectly disposed at the first main surface 5a with a dielectric film interposed therebetween.

As illustrated in FIG. 3, each electrode finger of the second IDT electrode 27 includes a third surface 27a, a fourth surface 27b, a side surface 27c. The third surface 27a and the fourth surface 27b are opposed to each other in the thickness direction of each electrode finger. Of the third surface 27a and the fourth surface 27b, the third surface 27a is located closer to the piezoelectric layer 5. The side surface 27c is connected to the third surface 27a and the fourth surface 27b. In the present example embodiment, the side surface 27c of each electrode finger is inclined with respect to the thickness direction of each electrode finger. More specifically, the side surface 27c of each electrode finger is inclined to reduce the width of the electrode finger further as it extends farther from the piezoelectric layer 5. The side surface 27c of each electrode finger may extend parallel or substantially parallel to the thickness direction of each electrode finger.

As described above, in example embodiments of the present invention, in at least one electrode finger of the first IDT electrode 7, the angle of inclination of the first portion 7d and the angle of inclination of the second portion 7e may differ from each other. Preferably, the angle of inclination of the first portion 7d and the angle of inclination of the second portion 7e differ from each other in multiple electrode fingers. More preferably, the angle of inclination of the first portion 7d and the angle of inclination of the second portion 7e differ from each other in all of the electrode fingers. Thus, the joining force between the first IDT electrode 7 and the intermediate layer 4 can be effectively improved. This structure thus reduces or prevents separation between the first IDT electrode 7 and the intermediate layer 4.

In the first IDT electrode 7 according to the present example embodiment, in each electrode finger, neither the angle of inclination of the first portion 7d nor the angle of inclination of the second portion 7e is 0°. Nevertheless, either the angle of inclination of the first portion 7d or the angle of inclination of the second portion 7e may be 0° or approximately 0°.

In each electrode finger of the first IDT electrode 7, the angle of inclination of the second portion 7e is greater than the angle of inclination of the first portion 7d. Instead, the angle of inclination of the second portion 7e may be smaller than the angle of inclination of the first portion 7d.

The side surface 7c of each electrode finger of the first IDT electrode 7 in the acoustic wave device 1 includes multiple portions, that is, the first portion 7d and the second portion 7e. The multiple portions in the side surface 7c are not limited to two portions, and may be three or more portions. In the side surface 7c, three or more portions may be arranged in the thickness direction of the electrode finger, and end portions of adjacent portions may be connected to each other.

FIG. 4 is a cross-sectional front view of an acoustic wave device according to a second example embodiment of the present invention, at a portion near two pairs of electrode fingers in each of the first IDT electrode and the second IDT electrode.

The present example embodiment differs from the first example embodiment in that a side surface 37c of each electrode finger of a first IDT electrode 37 includes, as multiple portions, a first portion 37d, a second portion 37e, and a third portion 37f. The first portion 37d, the second portion 37e, and the third portion 37f are arranged in this order in the thickness direction of each electrode finger. The acoustic wave device according to the present example embodiment has the same or substantially the same structure as the acoustic wave device 1 according to the first example embodiment in points other than those described above.

In each electrode finger of the first IDT electrode 37, the angle of inclination of the second portion 37e is the largest among the angles of inclination of the multiple portions. The angle of inclination of the first portion 37d is the smallest among the angles of inclination of the multiple portions. Thus, the angle of inclination of the third portion 37f is greater than the angle of inclination of the first portion 37d, and smaller than the angle of inclination of the second portion 37e. In the above manner, the side surface 37c of each electrode finger has multiple portions having different angles of inclination. Thus, the joining force between the first IDT electrode 37 and the intermediate layer 4 can be effectively improved. This structure can thus effectively reduce or prevent separation between the first IDT electrode 37 and the intermediate layer 4.

In each electrode finger of the first IDT electrode 37, the relationship between the angles of inclination of the multiple portions of the side surface 37c is not limited to the above example. For example, the angles of inclination may increase in order from the first portion 37d to the second portion 37e, and then to the third portion 37f. Alternatively, the angles of inclination may decrease in the above order.

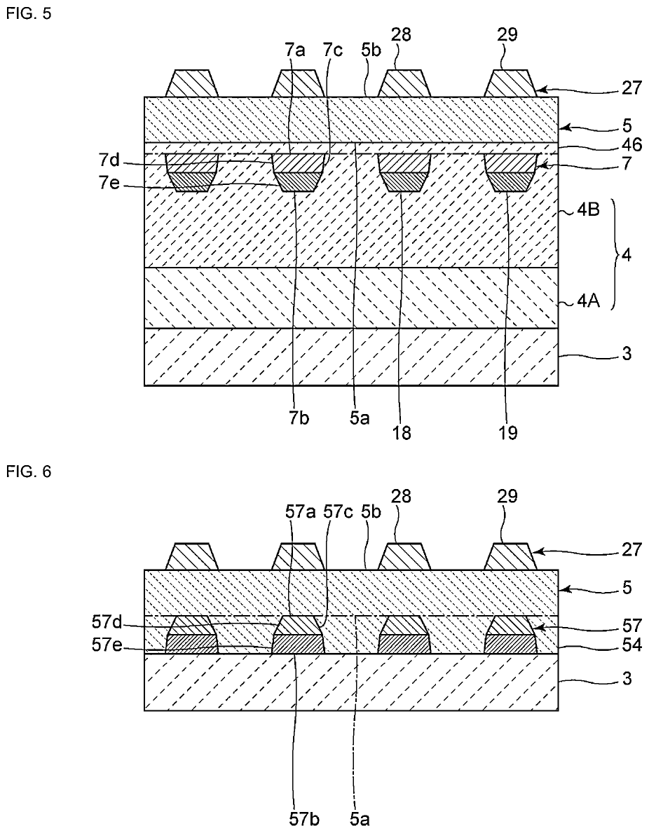

FIG. 5 is a cross-sectional front view of an acoustic wave device according to a third example embodiment of the present invention, at a portion near two pairs of electrode fingers in each of the first IDT electrode and the second IDT electrode.

The present example embodiment differs from the first example embodiment in that a dielectric film 46 is disposed between the piezoelectric layer 5 and the first IDT electrode 7. More specifically, the dielectric film 46 is directly disposed at the first main surface 5a of the piezoelectric layer 5. The first IDT electrode 7 is indirectly disposed at the first main surface 5a of the piezoelectric layer 5 with the dielectric film 46 interposed therebetween. A dot-and-dash line in FIG. 5 indicates a boundary between the dielectric film 46 and the intermediate layer 4. The acoustic wave device according to the present example embodiment has the same or substantially the same structure as the acoustic wave device 1 according to the first example embodiment in points other than those described above.

Silicon oxide, for example, is used as a material of the dielectric film 46. Nevertheless, the material of the dielectric film 46 is not limited to the above example. For example, a dielectric substance such as silicon nitride may be used.

The dielectric film 46 and the second layer 4B of the intermediate layer 4 are made of the same material to be an integrated unit. Instead, the dielectric film 46 and the second layer 4B of the intermediate layer 4 may be made of different materials.

In the present example embodiment, when the thickness of the dielectric film 46 is adjusted, a band width ratio of an acoustic wave device and a device capacitance can be easily adjusted. In addition, as in the case of the first example embodiment, the first IDT electrode 7 is embedded in the intermediate layer 4, and the angles of inclination of the first portion 7d and the second portion 7e of the side surface 7c of each electrode finger of the first IDT electrode 7 differ from each other. Thus, the joining force between the first IDT electrode 7 and the intermediate layer 4 can be improved. This structure thus reduces or prevents separation between the first IDT electrode 7 and the intermediate layer 4.

FIG. 6 is a cross-sectional front view of an acoustic wave device according to a fourth example embodiment of the present invention, at a portion near two pairs of electrode fingers in each of the first IDT electrode and the second IDT electrode.

The present example embodiment differs from the first example embodiment in the structure of an intermediate layer 54. The present example embodiment also differs from the first example embodiment in the structure of a side surface 57c of each electrode finger of a first IDT electrode 57. The acoustic wave device according to the present example embodiment has the same or substantially the same structure as the acoustic wave device 1 according to the first example embodiment in points other than those described above.

The intermediate layer 54 includes a single layer, and is made of a piezoelectric material. More specifically, the material of the intermediate layer 54 and the material of the piezoelectric layer 5 are the same. A dot-and-dash line in FIG. 6 indicates a boundary between the intermediate layer 54 and the piezoelectric layer 5. The first main surface 5a of the piezoelectric layer 5 is a plane along which a first surface 57a of each of the multiple electrode fingers of the first IDT electrode 57 extends.

The piezoelectric layer 5 and the intermediate layer 54 are made of the same material to be an integrated unit. Thus, in the acoustic wave device according to the present example embodiment, the first IDT electrode 57 is embedded in the piezoelectric layer. The piezoelectric layer in which the first IDT electrode 57 is embedded is a piezoelectric layer into which the piezoelectric layer 5 and the intermediate layer 54 illustrated in FIG. 6 are integrated. This piezoelectric layer is directly disposed on the support board 3.

The side surface 57c of each electrode finger of the first IDT electrode 57 is inclined to increase the width of the electrode finger further it farther as extends from the piezoelectric layer 5. In the side surface 57c, the angles of inclination of a first portion 57d and a second portion 57e are negative values. The angle of inclination of the second portion 57e is greater than the angle of inclination of the first portion 57d. The absolute value of the angle of inclination of the second portion 57e is smaller than the absolute value of the angle of inclination of the first portion 57d.

Also in the present example embodiment, as in the case of the first example embodiment, the first IDT electrode 57 is embedded in the intermediate layer 54, and the angles of inclination of the first portion 57d and the second portion 57e of the side surface 57c of each electrode finger of the first IDT electrode 57 are different from each other. Thus, the joining force between the first IDT electrode 57 and the intermediate layer 54 can be improved. This structure thus reduces or prevents separation between the first IDT electrode 57 and the intermediate layer 54.

As illustrated in FIG. 6, a second surface 57b of each of the multiple electrode fingers of the first IDT electrode 57 is in contact with the support board 3. During manufacture of the acoustic wave device according to the present example embodiment, for example, the first IDT electrode 57 may be disposed on the support board 3. Thereafter, a piezoelectric layer may be formed on the support board 3 to cover the first IDT electrode 57. The piezoelectric layer can be formed by, for example, sputtering. The piezoelectric layer is a piezoelectric layer into which the intermediate layer 54 and the piezoelectric layer 5 illustrated in FIG. 6 are integrated. Nevertheless, the method for forming the first IDT electrode 57 and the piezoelectric layer is not limited to the above example. For example, after the piezoelectric layer is formed, a groove portion may be formed in the piezoelectric layer. The first IDT electrode 57 may be disposed in this groove portion.

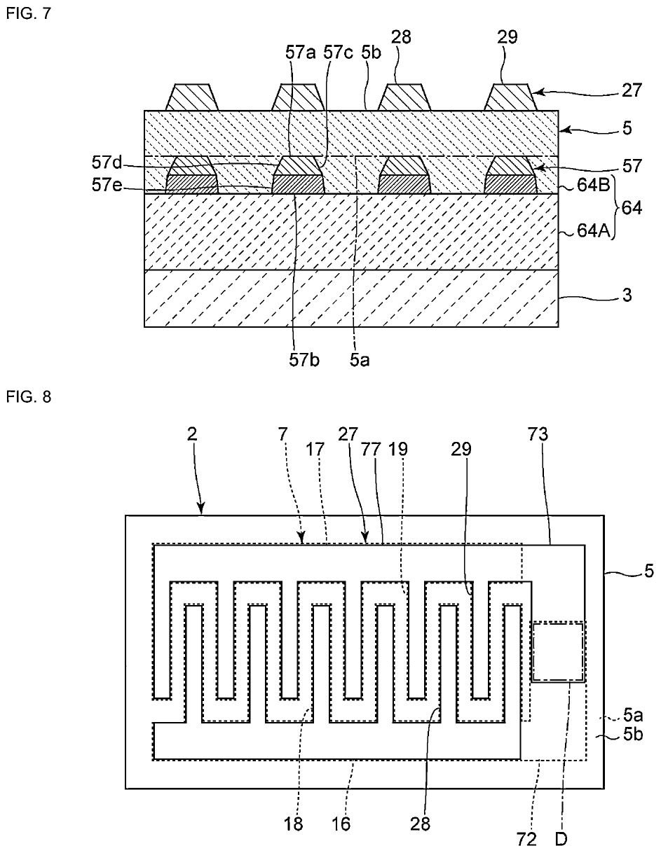

Instead, the second surface 57b of each of the multiple electrode fingers of the first IDT electrode 57 may be in no contact with the support board 3. For example, in a modified example of the fourth example embodiment illustrated in FIG. 7, an intermediate layer 64 includes multiple layers. More specifically, the intermediate layer 64 includes a first layer 64A and a second layer 64B. The first IDT electrode 57 is not embedded in the first layer 64A. The second layer 64B corresponds to a portion of the intermediate layer 64 in which the first IDT electrode 57 is embedded. The material of the second layer 64B and the material of the piezoelectric layer 5 are the same. In contrast, the material of the first layer 64A and the material of the piezoelectric layer 5 are different from each other. The second surface 57b of each electrode finger of the first IDT electrode 57 is in contact with the first layer 64A.

In the present modified example, the second layer 64B of the intermediate layer 64 and the piezoelectric layer 5 are integrated into a unit. The piezoelectric layer thus formed into an integrated unit is indirectly disposed on the support board 3 with the first layer 64A of the intermediate layer 64 interposed therebetween. As in the case of the fourth example embodiment, the structure of the present modified example thus reduces or prevents separation between the first IDT electrode 57 and the intermediate layer 64.

FIG. 8 is a schematic plan view of an acoustic wave device according to a fifth example embodiment of the present invention. FIG. 8 eliminates a reflector. FIG. 8 is a schematic plan view, and is viewed from the opposite side and illustrated upside down, with respect to FIG. 2 serving as a bottom view.

The present example embodiment differs from the first example embodiment in that it includes a first wiring 72 and a second wiring 73. The acoustic wave device according to the present example embodiment has the same or substantially the same structure as the acoustic wave device 1 according to the first example embodiment in points other than those described above. In the present example embodiment, the multiple fourth electrode fingers 29 of the second IDT electrode 27 are connected to a potential with a reverse phase to a potential of the multiple first electrode fingers 18 of the first IDT electrode 7.

The first wiring 72 is disposed at the first main surface 5a of the piezoelectric layer 5. The first wiring 72 is connected to the first busbar 16 of the first IDT electrode 7. The first wiring 72 is electrically connected to the multiple first electrode fingers 18 with the first busbar 16. In the present example embodiment, the first wiring 72 and the first busbar 16 are made of the same material to be an integrated unit. Nevertheless, the first wiring 72 and the first busbar 16 may be made of different materials.

The second wiring 73 is disposed at the second main surface 5b of the piezoelectric layer 5. The second wiring 73 is connected to a fourth busbar 77 of the second IDT electrode 27. The second wiring 73 is electrically connected to the multiple fourth electrode fingers 29 with the fourth busbar 77. In the present example embodiment, the second wiring 73 and the fourth busbar 77 are made of the same material to be an integrated unit. Nevertheless, the second wiring 73 and the fourth busbar 77 may be made of different materials.

In the present example embodiment, the multiple first electrode fingers 18 and the multiple fourth electrode fingers 29 are connected to potentials with reverse phases to each other. Thus, for example, when the first wiring 72, the first busbar 16, and the multiple first electrode fingers 18 have negative potentials, the second wiring 73, the fourth busbar 77, and the multiple fourth electrode fingers 29 have positive potentials.

As illustrated in FIG. 8, a portion of the first wiring 72 and a portion of the second wiring 73 overlap in a plan view. Thus, an overlapping region D is provided. More specifically, in the overlapping region D, the first wiring 72 and the second wiring 73 face each other with the piezoelectric layer 5 interposed therebetween. Thus, the device capacitance can be increased. This advantageous effect is described below while the present example embodiment is compared with the first example embodiment.

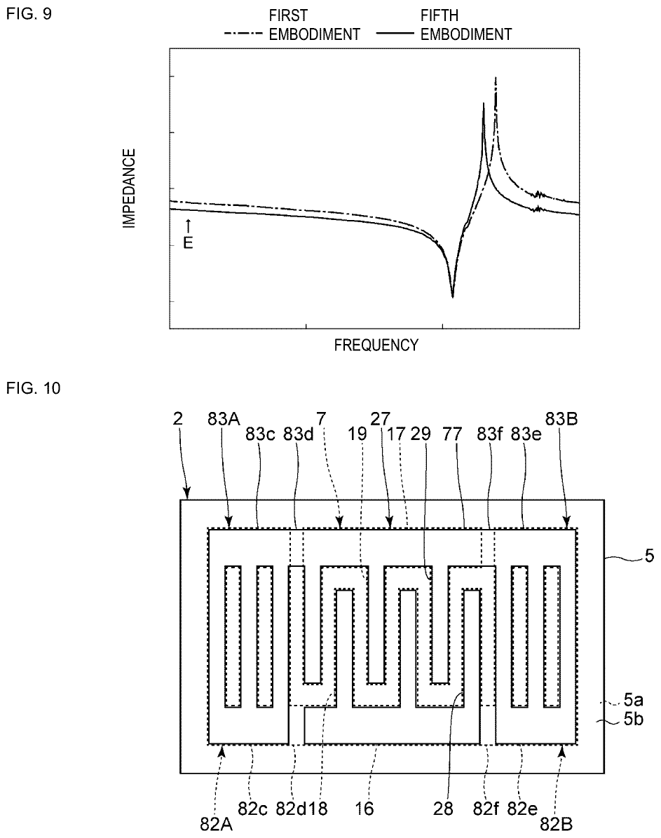

FIG. 9 is a graph of impedance frequency characteristics of the first example embodiment and the fifth example embodiment.

In a low frequency band width indicated with arrow E in FIG. 9, the impedance decreases further as the device capacitance increases further. At the frequency band width indicated with arrow E, the impedance according to the fifth example embodiment is lower than the impedance according to the first example embodiment. This graph indicates that the device capacitance can be increased in the fifth example embodiment. Thus, in the fifth example embodiment, the areas of the first IDT electrode 7 and the second IDT electrode 27 can be reduced to obtain desired device capacitance. Thus, the acoustic wave device according to the fifth example embodiment enables size reduction.

When the resonant frequency is denoted with fr, and the anti-resonant frequency is denoted with fa, a value expressed by (|fa−fr|/fr)×100[%] corresponds to a band width ratio of the acoustic wave device. As illustrated in FIG. 9, the difference between the resonant frequency fr and the anti-resonant frequency fa differs between the fifth example embodiment and the first example embodiment. Thus, the band width ratio differs between the fifth example embodiment and the first example embodiment. This is because the band width ratio depends on the device capacitance. In the fifth example embodiment, when the area of the overlapping region D is adjusted, the device capacitance can be easily adjusted. Thus, the band width ratio can be easily adjusted.

As in the case of the first example embodiment, also in the fifth example embodiment, the first IDT electrode 7 is embedded in the intermediate layer, and the angles of inclination of the first portion and the second portion of the side surface of each electrode finger of the first IDT electrode 7 differ from each other. Thus, the joining force between the first IDT electrode 7 and the intermediate layer can be improved. This structure thus reduces or prevents separation between the first IDT electrode 7 and the intermediate layer.

FIG. 8 schematically illustrates an arrangement of the first wiring 72 and the second wiring 73, and omits a reflector. For example, the overlapping region D may be located outside the reflector in the acoustic-wave propagation direction. In other words, for example, the reflector may be located between the overlapping region D and the first IDT electrode 7.

The fifth example embodiment includes one first wiring 72 and one second wiring 73. Instead, the fifth example embodiment may include two first wirings 72 and two second wirings 73.

FIG. 10 is a schematic plan view of an acoustic wave device according to a sixth example embodiment of the present invention.

The present example embodiment differs from the fifth example embodiment in that it includes two first wirings and two second wirings. More specifically, the two first wirings include a first wiring 82A and a first wiring 82B, and the two second wirings include a second wiring 83A and a second wiring 83B. The present example embodiment also differs from the fifth example embodiment in that the first wiring 82A, the first wiring 82B, the second wiring 83A, and the second wiring 83B are reflectors. The acoustic wave device according to the present example embodiment has the same or substantially the same structure as the acoustic wave device according to the fifth example embodiment in points other than those described above.

As in the case of the fifth example embodiment, the first wiring 82A and the first wiring 82B are disposed at the first main surface 5a of the piezoelectric layer 5. The first wiring 82A includes a reflector portion 82c and a wiring portion 82d. The reflector portion 82c defines and functions as a reflector. The wiring portion 82d is connected to the reflector portion 82c. The wiring portion 82d is connected to the first busbar 16 of the first IDT electrode 7. Similarly, the first wiring 82B includes a reflector portion 82e and a wiring portion 82f. The wiring portion 82f connects the reflector portion 82e and the first busbar 16 to each other. The reflector portion 82c and the reflector portion 82e face each other with the first IDT electrode 7 interposed therebetween.

The second wiring 83A and the second wiring 83B are disposed at the second main surface 5b of the piezoelectric layer 5. The second wiring 83A includes a reflector portion 83c and a wiring portion 83d. The wiring portion 83d connects the reflector portion 83c and the fourth busbar 77 to each other. Similarly, the second wiring 83B includes a reflector portion 83e and a wiring portion 83f. The wiring portion 83f connects the reflector portion 83e and the fourth busbar 77 to each other. The reflector portion 83c and the reflector portion 83e face each other with the second IDT electrode 27 interposed therebetween.

In the present example embodiment, the multiple first electrode fingers 18 and the multiple fourth electrode fingers 29 are connected to potentials with reverse phases to each other. Thus, when, for example, the first wiring 82A, the first wiring 82B, the first busbar 16, and the multiple first electrode fingers 18 have negative potentials, the second wiring 83A, the second wiring 83B, the fourth busbar 77, and the multiple fourth electrode fingers 29 have positive potentials.

The reflector portion 82c of the first wiring 82A and the reflector portion 83c of the second wiring 83A overlap in a plan view. More specifically, the reflector portion 82c and the reflector portion 83c face each other with the piezoelectric layer 5 interposed therebetween. Similarly, the reflector portion 82e of the first wiring 82B and the reflector portion 83e of the second wiring 83B overlap in a plan view. More specifically, the reflector portion 82e and the reflector portion 83e face each other with the piezoelectric layer 5 interposed therebetween. Thus, the device capacitance can be increased.

As in the cases of the first example embodiment and the fifth example embodiment, also in the present example embodiment, the first IDT electrode 7 is embedded in the intermediate layer, and the angles of inclination of the first portion and the second portion of the side surface of each electrode finger of the first IDT electrode 7 differ from each other. Thus, the joining force between the first IDT electrode 7 and the intermediate layer can be improved. This structure thus reduces or prevents separation between the first IDT electrode 7 and the intermediate layer.

In the present example embodiment, both of the first wiring 82A and the second wiring 83A are reflectors. Both of the first wiring 82B and the second wiring 83B are reflectors. Nevertheless, at least one of the first wiring 82A and the second wiring 83A may be a reflector. Similarly, at least one of the first wiring 82B and the second wiring 83B may be a reflector.

In the present disclosure, the acoustic wave device may include a protective film such as, for example, a silicon oxide film or a silicon nitride film to cover the second IDT electrode.

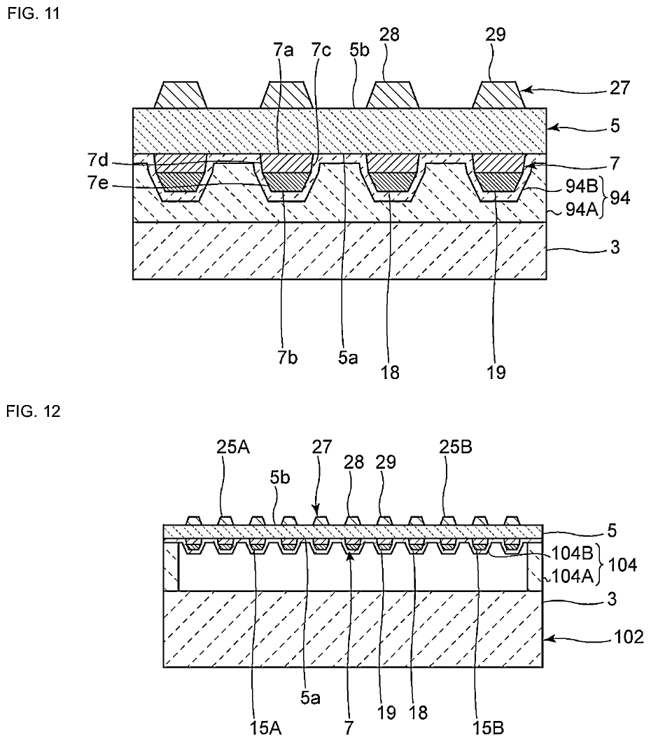

FIG. 11 is a cross-sectional front view of an acoustic wave device according to a seventh example embodiment of the present invention, at a portion near two pairs of electrode fingers in each of the first IDT electrode and the second IDT electrode.

The present example embodiment differs from the first example embodiment in that the thickness of a second layer 94B of an intermediate layer 94 is smaller than the thickness of each electrode finger of the first IDT electrode 7. The present example embodiment also differs from the first example embodiment in that a part of a first layer 94A of the intermediate layer 94 is located between electrode fingers of the first IDT electrode 7. The acoustic wave device according to the present example embodiment has the same or substantially the same structure as the acoustic wave device 1 according to the first example embodiment in points other than those described above.

In the present example embodiment, a portion of the intermediate layer 94 in which the first IDT electrode 7 is embedded corresponds to a portion of the intermediate layer 94 covering the first IDT electrode 7. More specifically, in the present example embodiment, the first IDT electrode 7 is embedded in the second layer 94B of the intermediate layer 94. As in the case of the first example embodiment, the angles of inclination of the first portion 7d and the second portion 7e of the side surface 7c of each electrode finger of the first IDT electrode 7 differ from each other. Thus, the joining force between the first IDT electrode 7 and the intermediate layer 94 can be improved. This structure thus reduces or prevents separation between the first IDT electrode 7 and the intermediate layer 94.

The support board 3 may face the first IDT electrode 7 embedded in the intermediate layer 94 with a hollow portion interposed therebetween. For example, in a modified example of the seventh example embodiment illustrated in FIG. 12, a first layer 104A of an intermediate layer 104 has a frame shape. In contrast, a second layer 104B of the intermediate layer 104 covers the first IDT electrode 7, as in the case of the seventh example embodiment. More specifically, the first IDT electrode 7 is embedded in the second layer 104B of the intermediate layer 104.

The hollow portion is defined by the first layer 104A and the second layer 104B of the intermediate layer 104 and the support board 3. A piezoelectric substrate 102 thus includes a hollow portion. The support board 3 faces the first IDT electrode 7 embedded in the second layer 104B of the intermediate layer 104 with the hollow portion interposed therebetween. As in the case of the seventh example embodiment, the modified example also reduces or prevents separation between the first IDT electrode 7 and the second layer 104B of the intermediate layer 104.

In the present modified example, the materials of the first layer 104A and the second layer 104B of the intermediate layer 104 differ from each other. Nevertheless, the first layer 104A and the second layer 104B may be made of the same material even when the first layer 104A has a frame shape.

The structure where the second layer of the intermediate layer has a frame shape and the piezoelectric substrate has a hollow portion may be used as a structure other than the present modified example. For example, the first layer 4A of the intermediate layer 4 in the first example embodiment illustrated in FIG. 1 may have a frame shape. Alternatively, the first layer 64A of the intermediate layer 64 in the modified example of the fourth example embodiment illustrated in FIG. 7 may have a frame shape. These structures also reduces or prevents separation between the first IDT electrode and the second layer of the intermediate layer.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device, comprising:
a support board;
an intermediate layer on the support board;
a piezoelectric layer on the intermediate layer, and including a first main surface located closer to the intermediate layer and a second main surface opposed to the first main surface;
a first IDT electrode at the first main surface of the piezoelectric layer, and embedded in the intermediate layer; and
a second IDT electrode at the second main surface of the piezoelectric layer; wherein
the first IDT electrode includes a plurality of electrode fingers each including a first surface and a second surface opposed to each other in a thickness direction of the plurality of electrode fingers, and a side surface connected to the first surface and the second surface; and
the side surface of each of the plurality of electrode fingers of the first IDT electrode includes a first portion and a second portion, and in at least one of the plurality of electrode fingers, the first portion and the second portion have different angles of inclination with respect to the thickness direction of the electrode finger.

2. The acoustic wave device according to claim 1, wherein, in each of the plurality of electrode fingers in the first IDT electrode, the angles of inclination of the first portion and the second portion of the side surface with respect to the thickness direction of the electrode finger are different from each other.

3. The acoustic wave device according to claim 1, wherein a material of a portion of the intermediate layer in which the first IDT electrode is embedded and a material of the piezoelectric layer are different from each other.

4. The acoustic wave device according to claim 3, wherein the first IDT electrode is directly provided at the first main surface of the piezoelectric layer.

5. The acoustic wave device according to claim 3, further comprising:
a dielectric film directly at the first main surface of the piezoelectric layer; wherein
the first IDT electrode is indirectly provided at the first main surface of the piezoelectric layer with the dielectric film interposed therebetween.

6. The acoustic wave device according to claim 1, wherein a material of a portion of the intermediate layer in which the first IDT electrode is embedded and a material of the piezoelectric layer are the same.

7. The acoustic wave device according to claim 1, wherein the intermediate layer includes a plurality of layers including different materials.

8. The acoustic wave device according to claim 1, wherein
the plurality of electrode fingers of the first IDT electrode include a plurality of first electrode fingers and a plurality of second electrode fingers connected to potentials different from each other;
the second IDT electrode includes a plurality of third electrode fingers and a plurality of fourth electrode fingers connected to potentials different from each other, and the plurality of fourth electrode fingers are connected to a potential with a reverse phase to a potential of the plurality of first electrode fingers;
the acoustic wave device further includes:
a first wiring electrically connected to the plurality of first electrode fingers of the first IDT electrode; and
a second wiring electrically connected to the plurality of fourth electrode fingers of the second IDT electrode; and
a portion of the first wiring and a portion of the second wiring overlap in a plan view.

9. The acoustic wave device according to claim 8, wherein at least one of the first wiring and the second wiring is a reflector.

10. The acoustic wave device according to claim 1, wherein each of the plurality of electrode fingers extends in a direction parallel or substantially parallel to each other.

11. The acoustic wave device according to claim 1, wherein the first IDT electrode includes a laminate including a Pt layer and an Al layer.

12. The acoustic wave device according to claim 1, wherein the second IDT electrode includes an Al layer.

13. The acoustic wave device according to claim 1, wherein the support board includes silicon.

14. The acoustic wave device according to claim 7, wherein the plurality of layers of the intermediate layer include a first layer and a second layer.

15. The acoustic wave device according to claim 14, wherein the first layer includes silicon nitride.

16. The acoustic wave device according to claim 14, wherein the second layer includes silicon oxide.

17. The acoustic wave device according to claim 1, wherein the piezoelectric layer includes lithium niobate.

18. The acoustic wave device according to claim 5, wherein the dielectric film includes silicon oxide.

19. The acoustic wave device according to claim 1, wherein the intermediate layer includes a single layer including a piezoelectric material.
